(19) United States
(12) Patent Application Publication
(10) Pub. No.: US 2007/0167037 A1
(43) Pub. Date: Jul. 19, 2007

(54) Electric sub-assembly comprising an electrically conductive contact pin for pressing into an opening of a printed circuit board

(75) Inventors: Wolfgang Thiel, Denkendorf (DE); Dirk Riese, Nurnberg (DE); Jorg Graubmann, Eichstatt (DE)

Correspondence Address: CONTINENTAL TEVES, INC., ONE CONTINENTAL DRIVE, AUBURN HILLLS, MI, 48326-1581, US

(73) Assignee: Conti Temic Microelectronic, GMBH

(21) Appl. No.: 10/589,145

(22) PCT Filed: Dec. 24, 2004
(86) PCT No.: PCT/DE04/02814

§ 371 Date: Aug. 11, 2006

(30) Foreign Application Priority Data
Feb. 11, 2004 (DE) 10 2004 006 533.0

(51) Int. Cl. H05K 1/00

(52) U.S. Cl. 439/70

(57) ABSTRACT

The invention relates to an electric sub-assembly comprising conductor tracks on its upper and lower faces and non-plated holes (2), the hole (2) in the printed circuit board having predetermined dimensions (D2) and at least one sub-section of the contact pin (1) being oversized (D1.1>D2) in a defined manner in relation to the dimensions (D2) of the hole, in order to form a press connection. The length (l1) of the contact pin (1) that can be introduced is greater than the depth (l2) of the opening (2), so that the contact pin (1), once pressed into the hole, passes through the printed circuit board (2) and projects beyond the latter in the introduction direction.

### BACKGROUND OF THE INVENTION

The invention relates to an electric sub-assembly comprising an electrically conductive contact pin for pressing into an opening of a printed circuit board. The electric sub-assembly consisting of a non-plated printed circuit board (2) with electric conductor tracks (3, 6) on the lower and upper side, characterized in that an electric connection is made between the conductor tracks (3, 6) on the upper and lower side by at least one electrically conductive contact pin (1), wherein the printed circuit board comprises at least one non-metallized opening (2); the opening (2) of the printed circuit board comprises predetermined dimensions (D2) and for forming a press connection the contact pin (1) comprises over a first partial length (11.1) a defined oversize (D1.1>D2) in relation to the dimensions (D2) of the opening; and comprises a second partial length (11.2) that lies in front of the introduction direction with an undersize (D1.2<D2), which is smaller than the dimension of the opening (D2); the first partial length (11.1) being smaller than the depth (12) of the opening (2) of the printed circuit board, so that after being introduced at least one part of the second partial length (11.2) remains in the opening; the length (11), that can be introduced, of the contact pin (1) is greater than the depth (12) of the opening (2) so that the contact pin (1) once pressed into the hole, passes through the printed circuit board (2) and projects beyond the latter in the introduction direction.

Pressing contact pins of this type are formed in massive manner from a full piece or in elastic manner by embodying spring openings. Here, the opening of the printed circuit board is metallized, and has predetermined dimensions, i.e. a diameter in case of the usually provided round openings. In contrast, the contact pin has a defined oversize at least in one sub-section to form a press connection in relation to the dimensions of the opening, what defines a press fit. Moreover, as a rule, the length of the contact pin that can be introduced is greater than the depth of the opening, so that the contact pin, once pressed into the hole, passes through the printed circuit board and projects beyond the latter in the introduction direction.

In particular, with massive contact pins deformations in the edge section of the openings appear with printed circuit boards, especially with those made of CEM- or FR4-materials, due to the forces during pressing in. In particular, with non-plated openings there is a risk that the conductor track, lying on the face opposite to the introduction direction of the contact pin, is not contacted. Particularly, also sections of the dielectric basic material of the printed circuit board can be pushed between the contact pin and the conductor track of the printed circuit board once pressed into the pressing direction. As the dielectric basic material is not capable of being moistened even during a soldering process, contacting cannot be established in such case.

### SUMMARY OF THE INVENTION

It is the object of the invention to indicate an electric sub-assembly, which circumvents these problems. This object is achieved by an electric sub-assembly consisting of a non-plated printed circuit board (2) with electric conductor tracks (3, 6) on the lower and upper side, characterized in that an electric connection is made between the conductor tracks (3, 6) on the upper and lower side by at least one electrically conductive contact pin (1), wherein the printed circuit board comprises at least one non-metallized opening (2); the opening (2) of the printed circuit board comprises predetermined dimensions (D2) and for forming a press connection the contact pin (1) comprises over a first partial length (11.1) a defined oversize (D1.1>D2) in relation to the dimensions (D2) of the opening; and comprises a second partial length (11.2) that lies in front of the introduction direction with an undersize (D1.2<D2), which is smaller than the dimension of the opening (D2); the first partial length (11.1) being smaller than the depth (12) of the opening (2) of the printed circuit board, so that after being introduced at least one part of the second partial length (11.2) remains in the opening; the length (11), that can be introduced, of the contact pin (1) is greater than the depth (12) of the opening (2) so that the contact pin (1) once pressed into the hole, passes through the printed circuit board (2) and projects beyond the latter in the introduction direction.

### BRIEF DESCRIPTION OF THE DRAWINGS

The invention will be described in more detail in the following taken in conjunction with Figures and examples of embodiments, in which:

FIG. 1 shows a sub-assembly with a contact pin according to the invention

FIG. 2 shows a contact pin and a printed circuit board before pressing in.

### DETAILED DESCRIPTION OF THE DRAWINGS

For avoiding the deformations and, if applicable, herewith involved electrical contact problems the contact pin is oversized only in a first partial length 11.1 in relation to the dimensions of the opening 2, i.e. the diameter D1.1 which is greater in relation to the diameter D2 of the opening extends only over a part of the contact pin and in the introduction direction a second partial length (11.2) that lies in front of the first partial length with an undersize (D1.2<D2) is provided, which is smaller than the dimension of the opening (D2).

Here, the first partial length 11.1 is smaller than the depth 12 of the hole 2 of the printed circuit board, in such a way that once the pin has been introduced, at least one part of the second partial length 11.2 remains in the hole. This ensures that during pressing in even with massive contact pins there are no or clearly low deformations of the printed circuit board on the face lying opposite in the introduction direction. Thus, after pressing in a space 7 remains between the contact pin 1 and the opening 5 in the lower edge section, which space with a wise dimensioning is enough to enable a rising of a perpendicular 8 in these spaces 7.

Once pressed into the hole, the edge of the first partial length 11.1 of the contact pin 1 with the oversize D1 contacts the edge 3.2 of the contact zone 3, which corresponds to the dimensions of the opening 2. This results preferably in a cold welding between the contact pin 1 and the contact zone 3 at its edge 3.2 and at the upper side of the printed circuit board a gas-tight solder-less press connection is made between the contact pin 1 and the contact zone 3.

The length 11, that can be introduced, of the contact pin 1 is limited by the stop 1.3 formed by the contact pin, the latter being preferably formed axially symmetrical or circumferential at least at two sides for an improved force distribution.

In the shown embodiment the second partial section 11.2 comprises an area of transition to the first partial section 11.1, in which a constant tapering is effected. Thereby, twisting during introduction and a relative concentrical alignment of the contact pin 1 towards the opening 2 are possible.

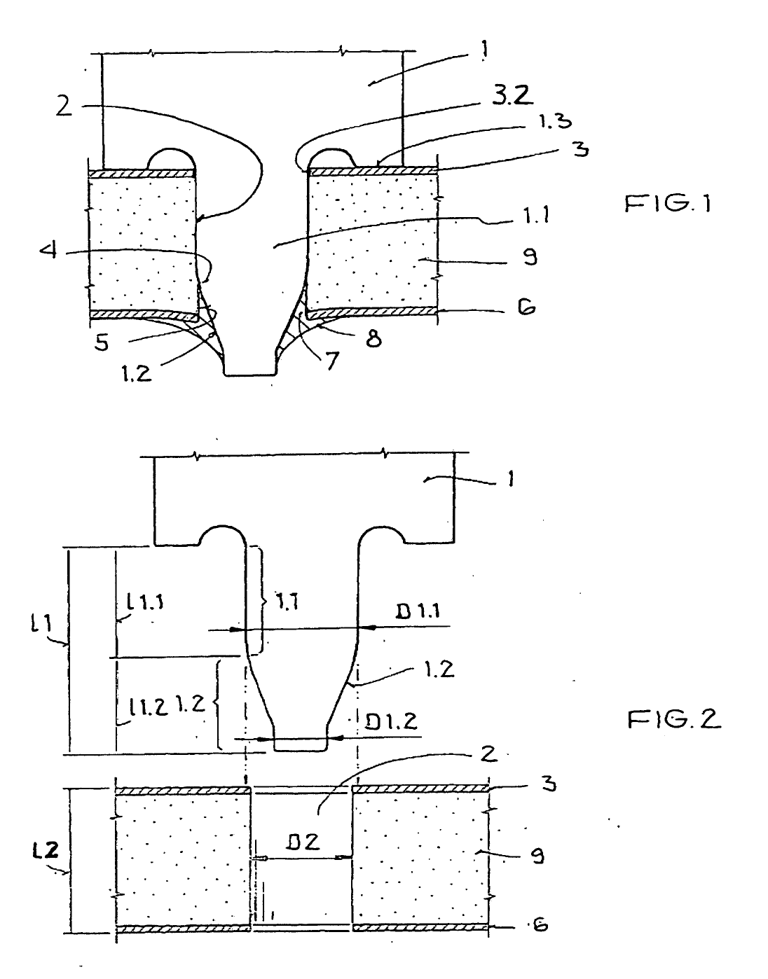

A contact pin of this type is preferably flow soldered to the printed circuit board on the face lying opposite to the introduction direction of the contact pin. The special advantage of this contact pin becomes apparent if one looks at a corresponding connection, which is drafted in FIG. 1. There, by flowing in of the perpendicular during the flow soldering, the lower deformation in the lower edge section of the opening 2 of the printed circuit board and the forming of a good soldering connection on the lower side can be recognized, wherein hardly any dielectric printed circuit board material 9 is deformed in this edge section, at least is not brought as far as into the region between the contact pin and the conductor track 6, so that hardly any user problems arise.

A contact pin of this type can be used for connecting electric components of an electric sub-assembly to a printed circuit board, wherein at least one component comprises appropriate contact pins 1 and the contact pins 1 are electrically connected by flow soldering to a conductor track 6 of the printed circuit board 9 on the face lying opposite to the introduction direction.

Moreover, a contact pin of this type is suitable for forming a connection between electrical conductor tracks 3, 6 on the lower and upper side of a printed circuit board, by the contact pin 1 being pressed into an opening 2 of contact zones of the conductor tracks 3, 6 on the upper and lower side of the printed circuit board 9. Here, the stop 1.3 of the contact pin (1) on the face lying in the introduction direction touches the contact zone, located there, of the conductor track 3, whereas the contact pin 1 on the face lying opposite to the introduction direction is electrically connected by flow soldering to the contact zone, located there, of the conductor track 6.

Electric sub-assemblies of this type can be made up with a printed circuit board 9 made of low cost material, in particular CEM1, CEM3 or FR4, which so far had been unsuitable for sub-assemblies with press-in contact pins, particularly massive contact pins. Here, it is not necessary that the opening 2 in the printed circuit board 9 is metallized and can be punched in the printed circuit board 9.

Exactly for these low-cost printed circuit boards obvious cost savings can be achieved by means of the proposed contact pins in connection with the flow soldering process on the lower side.

1-7. (canceled)

8. An electric sub-assembly having a non-plated printed circuit board (2) with electric conductor tracks (3, 6) on the lower and upper side, the sub-assembly comprising:
at least one electrically conductive contact pin for providing an electric connection between two or more conductor tracks (3, 6) on an upper and lower side by at least one electrically conductive contact pin (1);
at least one non-metallized opening (2), wherein the opening (2) of the printed circuit board has predetermined dimensions (D2) and is for forming a press connection with the contact pin (1), and having over a first partial length (l1.1) a defined oversize (D1.1>D2) in relation to dimensions (D2) of the opening, and having a second partial length (l1.2) that lies in front of an introduction direction with an undersize (D1.2<D2), which is smaller than the dimension of the opening (D2), wherein the first partial length (l1.1) is smaller than a depth (l2) of the opening (2) of the printed circuit board, so that after being introduced at least one part of the second partial length (l1.2) remains in the opening, and the length (l1), that can be introduced, of the contact pin (1) is greater than the depth (l2) of the opening (2) so that the contact pin (1) once pressed into the hole, passes through the printed circuit board (2) and projects beyond the latter in the introduction direction; and
two or more contact zones are provided around the opening (2) on the upper and lower side of the printed circuit board (9), wherein the contact zones form an edge corresponding to the dimensions (D2) of the opening (2), so that the contact pin (1) once the pin has been pressed into the hole on the face lying in the introduction direction contacts the contact zone (3), located there, of the conductor track, and the contact pin (1) on the face opposite to the introduction direction is electrically connected by flow soldering to the contact zone (6), located there, of the conductor track.

9. An electric sub-assembly according to claim 8, wherein a second sub-section (l1.2) of the contact pin comprises an area of transition to a first sub-section (l1.1), in which a constant tapering is effected.

10. An electric sub-assembly according to claim 8, wherein the contact pin (1) is formed in massive manner.

11. An electric sub-assembly according to claim 8, wherein a printed circuit board (9) made of CEM- or FR4-material is used.

12. An electric sub-assembly according to claim 8, wherein a stop (1.3) is provided, which defines the length (l1), that can be introduced, of the contact pin (1).

13. An electric sub-assembly according to claim 8, wherein when pressing in the contact pin (1) on the face lying in the introduction direction the edge of the contact zone (3), located there, is cold-welded with the contact pin (1) and that on the upper side of the printed circuit board a gas-tight and solder-free press connection is made between the contact pin (1) and the contact zone (3).

14. An electric sub-assembly according to claim 8, wherein the opening (2) is punched in the printed circuit board (9).
